(19) United States
(12) Patent Application Publication
(10) Pub. No.: US 2025/0366247 A1
(43) Pub. Date: Nov. 27, 2025

(54) IMAGE SENSOR INTEGRATED CIRCUIT WITH ISOLATION STRUCTURE AND METHOD

(71) Applicant: Taiwan Semiconductor Manufacturing Co., Ltd., Hsinchu (TW)

(72) Inventors: Shu Yen Kung, Hsinchu (TW); Jia-Hong Liou, Hsinchu (TW); Sheng Chieh Chuang, Hsinchu (TW); Chun-Chang Chen, Hsinchu (TW); Wei-Lin Chang, Hsinchu (TW); Ming Chyi Liu, Hsinchu (TW); Tsun-Kai Tsao, Hsinchu (TW)

(73) Assignee: Taiwan Semiconductor Manufacturing Co, Ltd., Hsinchu (TW)

(21) Appl. No.: 19/294,195

(22) Filed: Aug. 7, 2025

Related U.S. Application Data
(62) Division of application No. 17/832,380, filed on Jun. 3, 2022.
(60) Provisional application No. 63/320,595, filed on Mar. 16, 2022.

(51) Int. Cl. H10F 39/00; H10F 39/12; H10F 39/18

(52) U.S. Cl. CPC H10F 39/807; H10F 39/014; H10F 39/18; H10F 39/199

(57) ABSTRACT

A method includes: forming a masking layer on a backside of a substrate, the substrate including pixel regions having photodetectors, transistors being positioned on or in a frontside of the substrate; forming a mask opening in the masking layer by exposing the masking layer to patterned light, the opening including: mask pixel regions that mask the pixel regions; and mask protrusion regions that extend from the mask pixel regions toward a mask crossroad region; forming a substrate opening in the substrate by etching the substrate through the mask opening; and forming an isolation structure in the substrate opening.

### PRIORITY CLAIM

This application is a divisional application of U.S. Non-Provisional patent application Ser. No. 17/832,380 filed on Jun. 3, 2022, and claims benefit of U.S. Provisional Patent Application No. 63/320,595 filed on Mar. 16, 2022, which are incorporated by reference herein in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G are diagrammatic cross-sectional side and top views of a portion of an image sensor IC according to embodiments of the present disclosure.

FIGS. 2A-2F are diagrammatic cross-sectional side and top views of a crossroad portion of an image sensor IC according to embodiments of the present disclosure.

FIGS. 3A-3Q are views of an image sensor IC at various stages of fabrication in accordance with various embodiments.

FIG. 4 is a flowchart illustrating a method of fabricating an image sensor IC according to various aspects of the present disclosure.

FIG. 5 is a diagram of a lithography exposure system in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms. Such terms may be process- and/or equipment-dependent, and should not be interpreted as more or less limiting than a person having ordinary skill in the art would recognize as normal for the technology under discussion.

The present disclosure is generally related to semiconductor devices, and more particularly to image sensor integrated circuits (ICs), such as backside illumination (BSI) image sensor ICs including backside deep trench isolation (BDTI) structures. BDTI structures having very high aspect ratio and high uniformity are beneficial for the electrical isolation in complementary metal-oxide-semiconductor (CMOS) image sensors and photo detectors.

The BDTI structure overlaps a floating diffusion node, and is formed following formation of the floating diffusion node, such that the floating diffusion node underlies an opening in which the BDTI structure is formed. An etching process that forms the opening may suffer a loading effect at the crossroad regions, such that BDTI structure depth at the crossroad regions is greater than that at walls of the BDTI structure. This effect is worsened when the opening is formed using lower etching power. The worsened loading effect dramatically degrades isolation performance, as depth of the walls is reduced to prevent the deeper depth of the crossroad region resulting in contact with (e.g., damage to) the floating diffusion node.

Embodiments of the disclosure include an improved optical proximity correction (OPC) process that achieves high aspect ratio and highly uniform BDTI structures. By reducing dimensions of the crossroad region, loading effect at the crossroad region is reduced. BDTI improvements, including increased depth uniformity, enable smaller pixel sizes not only for partial BDTI structures but also for full BDTI structures, which paves the way for image sensor ICs having increased pixel density.

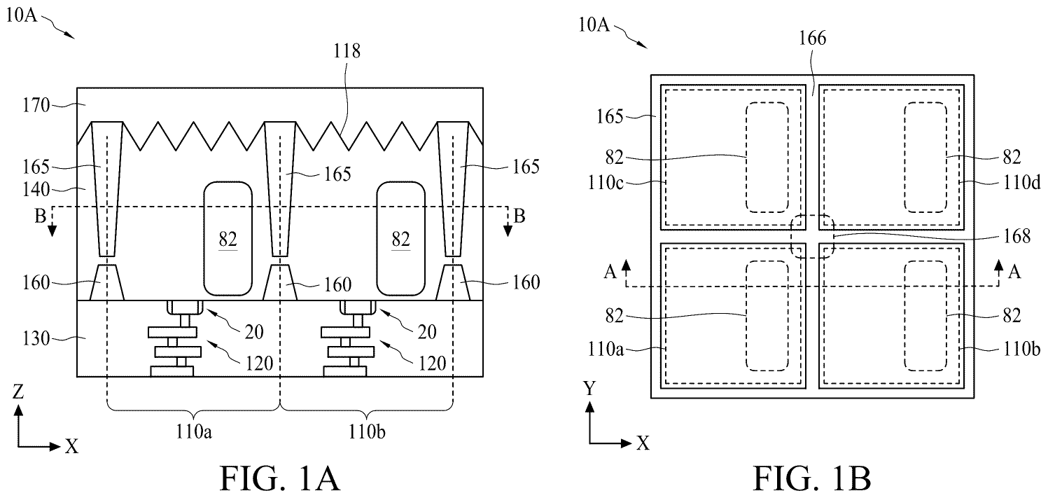

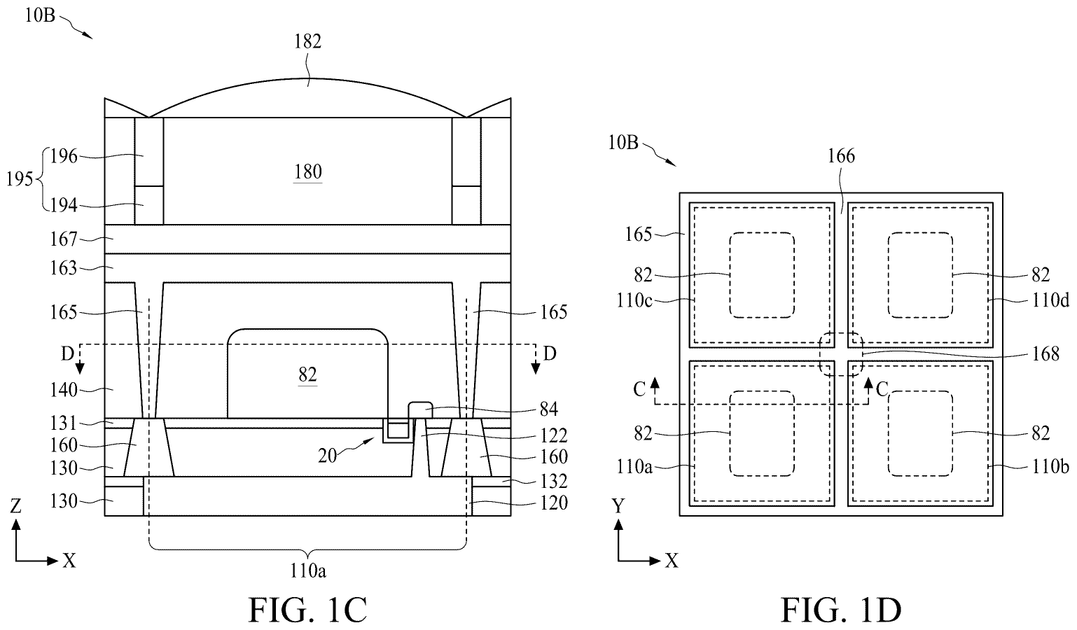

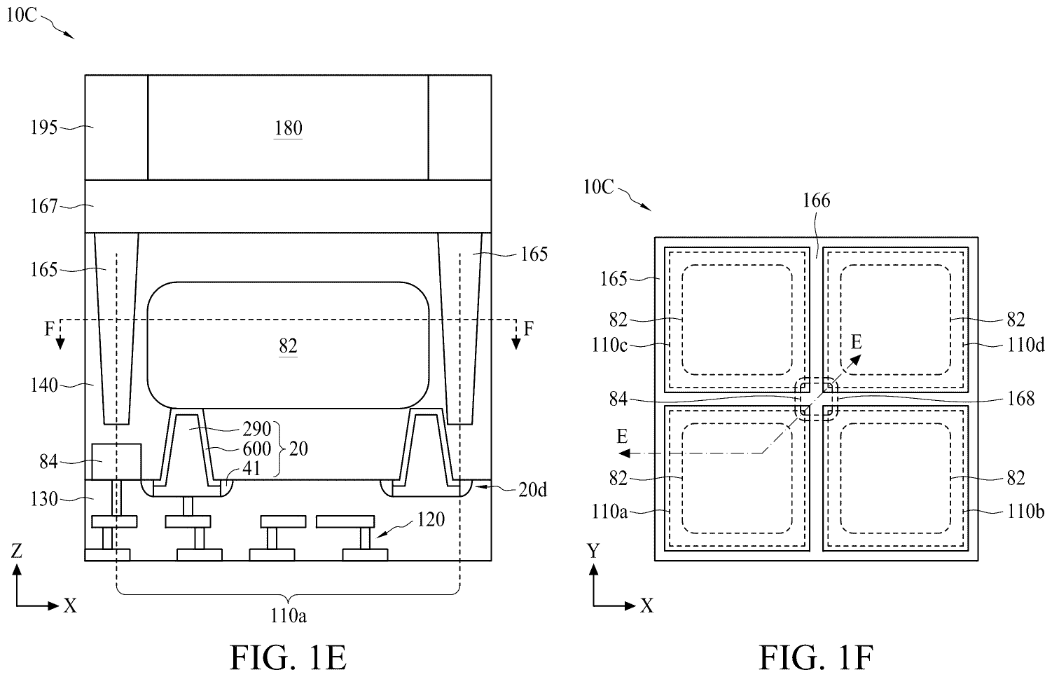

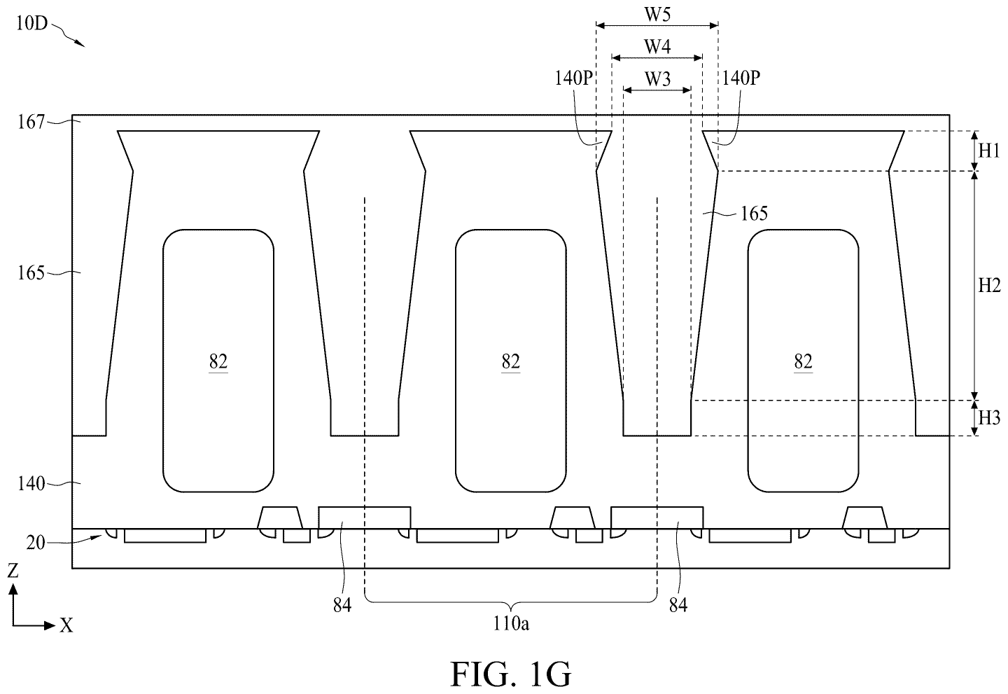

FIG. 1A illustrates a cross-sectional side view of an image sensor integrated circuit (IC) 10A in accordance with various embodiments. FIG. 1B illustrates a cross-sectional top view of the image sensor IC 10A along line B-B of FIG. 1A.

The image sensor IC 10A comprises a substrate 140 having a plurality of pixel regions 110a, 110b, 110c and 110d, which may be referred to collectively as the pixel regions 110a-110d. In some embodiments, the pixel regions 110a-110d are arranged in a matrix or grid, as illustrated in FIG. 1B.

The pixel regions 110a-110d comprise respective photodetectors 82, such as one photodetector 82 per pixel region 110a-110d. In some embodiments, the photodetector 82 includes one or more of a photodiode, a phototransistor, or the like. The photodetector 82 converts incident radiation (e.g., photons) into an electric signal. For example, the photodetector 82 may generate electron-hole pairs from the incident radiation. In some embodiments, the incident radiation includes one or more ranges of wavelengths. For examples, the wavelengths may be in a visible spectrum, an infrared spectrum, or the like. The electrical signal may be associated with one or more of the wavelengths.

A plurality of transistor gate structures 20 are arranged along a first side (e.g., a front side) of the substrate 140. The transistor gate structures 20 may be gate structures of field-effect transistors (FETs), such as planar FETs, fin-type FETs (FinFETs), nanostructure FETs or the like. The nanostructure FETs may include nanosheet FETs (NSFETs), nanowire FETs (NWFETs), or the like.

An interconnect structure, which may be a back-end-of-the-line (BEOL) metallization stack, is arranged along the first side of the substrate 140. The interconnect structure comprises a dielectric structure 130 surrounding a plurality of conductive interconnect layers 120. In some embodiments, the dielectric structure 130 comprises a plurality of stacked inter-level dielectric (ILD) layers. In some embodiments, the plurality of conductive interconnect layers 120 comprise alternating layers of conductive vias and conductive wires, which are electrically coupled to the plurality of transistor gate structures 20.

In some embodiments, isolation structures (e.g., shallow trench isolation structures, deep trench isolation structures, isolation implants, etc.) may be arranged within the substrate 140 at locations between adjacent ones of the plurality of pixel regions 110a-110d. For example, in some embodiments, shallow trench isolation (STI) structures 160 may be arranged within the first side of the substrate 140 between adjacent ones of the plurality of pixel regions 110a-110d. In some embodiments, back-side deep trench isolation (BDTI) structures 165 may be arranged within a second side of the substrate 140 opposite the first side, for example, between the adjacent ones of the plurality of pixel regions 110a-110d. In some embodiments, the BDTI structures 165 may be directly over the shallow trench isolation structures 160. In some embodiments, the BDTI structures 165 overlap the shallow trench isolation structures 160, for example, in a top view. In some embodiments, the BDTI structures 165 extend completely through the substrate 140 and the shallow trench isolation structures 160 may be omitted. In some embodiments, the BDTI structures 165 are a single, interconnected structure, as shown in the top view of FIG. 1B. Similarly, the shallow trench isolation structures 160 may be a single, interconnected structure. The BDTI structure 165 and the STI structure 160 may have a grid shape including walls 166 that join or overlap at crossroad regions 168. The walls 166 may include vertical walls that extend in a first direction (e.g., the Y-axis direction) and horizontal walls that extend in a second direction (e.g., the X-axis direction). The crossroad regions 168 may be regions of overlap of the vertical walls and the horizontal walls.

The second side of the substrate 140 may include a plurality of topographical features 118 arranged within the plurality of pixel regions 110a-110d. The plurality of topographical features 118 (e.g., pyramidal shaped protrusions and/or depressions) include a plurality of interior surfaces of the substrate 140. In some embodiments, one or more dielectric layers 170 are arranged over the second side of the substrate 140, for example, between the plurality of interior surfaces when present. In some embodiments, the one or more dielectric layers 170 may comprise an oxide, a nitride, a carbide, or the like. The angles of the plurality of interior surfaces increase absorption of radiation by the substrate 140 (e.g., by reducing reflection of radiation from the uneven surface). The plurality of interior surfaces may further act to reduce an angle of incidence for incident radiation having a steep angle with respect to a top of the one or more dielectric layers 170, thereby preventing the incident radiation from reflecting from the substrate 140. In some embodiments, the topographical features 118 are not present, for example, such that the upper surface of the substrate 140 is substantially coplanar with upper surfaces of the BDTI structures 165.

FIG. 1C illustrates a cross-sectional side view an image sensor IC 10B in accordance with various embodiments. The cross-sectional side view may, for example, be taken across the line C-C illustrated in FIG. 1D. FIG. 1D illustrates a cross-sectional top view of the image sensor IC 10B taken along the line D-D of FIG. 1C. The image sensor IC 10B is similar in many respects to the image sensor IC 10A illustrated in FIGS. 1A and 1B, and like reference numerals refer to like components or structures. Some description of certain components may be omitted for brevity.

The image sensor IC 10B comprises pixel regions 110a-110d. The image sensor IC 10B comprises a substrate 140, a photodetector 82 in the substrate 140, a first etch stop layer 131 along a lower surface of the substrate 140, dielectric layers 130 along a lower surface of the first etch stop layer 131, a second etch stop layer 132 between the dielectric layers 130, and a first metal line 120 disposed within the dielectric layer 130 and the second etch stop layer 132. In some embodiments, the first metal line 120 may be used as a metal reflector. In some embodiments, the image sensor IC 10B comprises an interconnect structure (not labeled) below the substrate 140, which may be similar to the interconnect structure described with reference to FIG. 1A.

A pixel isolation structure includes a substrate isolation structure 163 and a dummy contact structure 160. The substrate isolation structure 163 comprises isolation segments 165 (e.g., BDTI structures 165) that extend vertically through the substrate along a boundary of the pixel region 110a-110d. As a result, the isolation segments 165 laterally separate a first region of the substrate 140 from neighboring regions of the substrate 140 (and thus separates the photodetector 82 from neighboring photodetectors 82 (see FIG. 1D) that are in the neighboring regions of the substrate 140). Sidewalls of the isolation segments 165 border the first region of the substrate 140 that comprises the photodetector 82. The substrate isolation structure may be a grid structure or a ring-like structure, as shown in FIG. 1D. The substrate isolation structure may extend vertically from a top surface of the substrate 140 to a bottom surface that is below the top surface of the substrate 140.

The dummy contact structure 160 comprises segments that extend from the first metal line 120 to the respective isolation segments 165. As a result, the segments laterally separate a first region of the dielectric layer 130 from neighboring regions of the dielectric layer 130. In some embodiments, the pixel isolation structure and the first metal line 120 completely enclose the first region of the substrate 140 and the first region of the dielectric layer 130.

The pixel isolation structure may reduce the likelihood that a photon which enters the pixel region 110a will exit the pixel region 110a and enter a neighboring pixel region (e.g., the pixel region 110b or the pixel region 110c). The substrate isolation structure reduces the likelihood of the photon entering the neighboring pixel region at the substrate 140. Further, the dummy contact structure 160 reduces the likelihood of the photon entering the neighboring pixel region at the dielectric layer 130. Thus, the pixel isolation structure may improve an isolation of the pixel region from neighboring pixel regions. In turn, less cross talk may occur between the pixel region and neighboring pixel regions, thereby improving QE and other performance metrics of the image sensor IC 10B.

In some embodiments, the substrate isolation structure comprises one or more isolation materials. The one or more isolation materials may, for example, comprise silicon dioxide, silicon nitride, a low k dielectric, hafnium oxide, aluminum oxide, a high k dielectric, tungsten, aluminum, another suitable material, or any combination of the foregoing. In some embodiments, the substrate isolation structure has a refractive index less than that of the substrate 140 to provide optical isolation via total internal reflection.

In some embodiments, the dummy contact structure 160 comprises a first metal material. The first metal material may, for example, comprise tungsten, copper, titanium, another suitable metal, or any combination of the foregoing. The dummy contact structure 160 may have a greater width than the BDTI structure 165 at an interface between the dummy contact structure 160 and the BDTI structure 165 (e.g., along a top surface of the dummy contact structure 160). Further, the dummy contact structure 160 may have a height that is less than that of the BDTI structure 165. Furthermore, the dummy contact structure 160 may have some other surface geometrics (e.g., multifaceted or bulbous in shape). It should be appreciated that the STI structure 160 shown in FIG. 1A is different than the dummy contact structure 160 shown in FIG. 1C. For example, the STI structure 160 is formed in the substrate 140, and may be formed of a dielectric material, such as silicon oxide, whereas the dummy contact structure 160 is formed on the substrate 140 and in the dielectric layer 130 and the first etch stop layer 131, and may be formed of the first metal material. In some embodiments, both the STI structure 160 and the dummy contact structure 160 are present.

In some embodiments, the image sensor IC 10B is a complementary metal-oxide-semiconductor (CMOS) image sensor or the like. In some embodiments, the substrate 140 may, for example, comprise a semiconductor material such as silicon or the like.

In some embodiments, the dielectric layers 130 may, for example, comprise silicon dioxide, silicon nitride, a low k dielectric, another suitable dielectric material, or any combination of the foregoing. The first etch stop layer 131 and the second etch stop layer 132 may, for example, comprise silicon nitride, silicon carbide, silicon carbonitride, another suitable dielectric, or any combination of the foregoing.

In some embodiments, the first metal line 120 comprises a second metal material. The second metal material may, for example, comprise copper, aluminum copper, tungsten, another suitable metal, or any combination of the foregoing.

The photodetector 82 may comprise a first doped semiconductor region and a surrounding region of the substrate 140. The first doped semiconductor region may form a p-n junction with the surrounding region of the substrate 140.

A pixel transistor 20 comprising a gate may be disposed along the front side of the substrate 140 and a floating diffusion (FD) region 84 may be disposed in the substrate 140 along the front side of the substrate. A first contact 122 may extend through the dielectric layer 130 to the first metal line 120 and may electrically couple the pixel transistor 20 and/or the FD region 84 to the first metal line 120 or some other suitable metal line. A buffer layer 167 may be disposed on a back side of the substrate 140 and may extend over the photodetector 82.

A color filter 180 may be disposed on the back side of the substrate 140 and over the photodetector 82. A composite metal grid (CMG) 195 may be disposed on the back side of the substrate 140 over the isolation segments 165 and the dummy segments 160 along a boundary of the pixel region 110a. The CMG 195 may comprise a metal grid layer 194 and a dielectric grid layer 196 over the metal grid layer 194. The color filter 180 may be disposed between sidewalls of the CMG 195. A micro-lens 182 may be disposed on the back side of the substrate 140 over the color filter 180 and thus over the photodetector 82. Photons may enter the image sensor IC 10B through the micro-lens 182. Thus, the photons may enter the substrate 140 through the back side of the substrate 140, thereby making the image sensor “back-side illuminated.”

In some embodiments, the pixel transistor 20 may, for example, comprise a transfer transistor, a source-follower transistor, a row select transistor, a reset transistor, some other pixel transistor, or another transistor.

In some embodiments, the FD region 84 and the first doped semiconductor region may, for example, comprise doped silicon or the like.

In some embodiments, the first contact 122 may, for example, comprise tungsten, copper, titanium, another suitable metal, or any combination of the foregoing.

In some embodiments, the buffer layer 167 may, for example, comprise silicon dioxide, silicon nitride, another suitable dielectric, or any combination of the foregoing.

In some embodiments, the metal grid layer 194 may, for example, comprise tungsten, copper, another suitable metal, or any combination of the foregoing. In some embodiments, the dielectric grid layer 196 may, for example, comprise silicon dioxide, silicon nitride, another suitable dielectric, or any combination of the foregoing.

It should be understood that the buffer layer 167, the color filter 180, the CMG 195 and the micro-lens 182 may be included in the image sensor IC 10A shown in FIG. 1A. For example, the buffer layer 167, the color filter 180, the CMG 195 and the micro-lens 182 may overlie the one or more dielectric layer 170 of the image sensor IC 10A. In some embodiments, the buffer layer 167 is one or more of the dielectric layers 170.

FIG. 1E illustrates a cross-sectional side view of an image sensor IC 10C in accordance with various embodiments. The view in FIG. 1E is taken along cross-sectional line E-E of FIG. 1F. FIG. 1F illustrates a cross-sectional top view of the image sensor IC 10C along the cross-sectional line F-F of FIG. 1E. The image sensor IC 10C is similar in many respects to the image sensor ICs 10A, 10B, and like reference numerals refer to like components. Some description of certain components may be omitted for brevity.

The image sensor IC 10C includes an interconnect structure 120 disposed along a front-side surface of a substrate 140. In some embodiments, the substrate 140 comprises a semiconductor body (e.g., bulk silicon) and may has a first doping type (e.g., p-type doping). A photodetector 82 is disposed within the substrate 140 and is configured to convert incident electromagnetic radiation (e.g., photons) into electrical signals. The photodetector 82 comprises a second doping type (e.g., n-type doping) different from (e.g., opposite) the first doping type. In some embodiments, the first doping type is n-type and the second doping type is p-type, or vice versa. A floating diffusion node 84 is disposed along the front-side surface of the substrate 140 and has the second doping type (e.g., n-type).

A vertical transfer transistor 20 and a dummy vertical transistor structure 20d are disposed along the front-side surface of the substrate 140. The vertical transfer transistor 20 and the dummy vertical transistor structure 20d may comprise a vertical gate electrode 290, a vertical gate dielectric layer 600, and a sidewall spacer structure 41. The vertical gate electrode 290 includes a conductive body and an embedded conductive structure extending from the conductive body into the substrate 140. The embedded conductive structure may extend from the front-side surface of the substrate 140 to a point vertically above the front-side surface. The vertical gate dielectric layer 600 surrounds the embedded conductive structure and is configured to electrically isolate the vertical gate electrode 290 from the substrate 140. The sidewall spacer structure 41 may continuously surround outer sidewalls of the vertical gate electrode 290. In some embodiments, the vertical gate electrode 290 is a single continuous material, such that the conductive body and the embedded conductive structure comprise a same material. The same material may, for example, be or comprise a conductive material, such as intrinsic polysilicon, aluminum, titanium, tungsten, a combination of the foregoing, or the like.

The interconnect structure 120 extends along the front-side surface of the substrate 140 and is configured to electrically couple doped regions of the substrate 140 (e.g., the floating diffusion node 84, the photodetector 82) and pixel devices (e.g., the vertical transfer transistor 20) to one another. The interconnect structure 120 includes an interconnect dielectric structure 130, a plurality of conductive wires and a plurality of conductive vias. A conductive via may directly contact a bottom surface of the vertical gate electrode 290 of the vertical transfer transistor 20, such that the vertical transfer transistor 20 is electrically coupled to other conductive structures and/or layers (e.g., the conductive wires) disposed within the interconnect dielectric structure 130. The interconnect dielectric structure 130 continuously extends across an entire bottom surface of the vertical gate electrode 290 of the dummy vertical transistor structure 20d, such that the dummy vertical transistor structure 20d is electrically isolated from other conductive structures and/or layers disposed within the interconnect dielectric structure 130.

A deep trench isolation (DTI) structure 165 (e.g., the BDTI structure 165) extends into a back-side surface of the substrate 140 to a point below the back-side surface. In some embodiments, the DTI structure 165 is disposed within a peripheral region of the image sensor IC 10C that laterally surrounds the photodetector 82. The photodetector 82 is disposed between inner sidewalls of the DTI structure 165. The DTI structure 165 is configured to electrically isolate the photodetector 82 from other semiconductor devices (e.g., other photodetectors (not shown)) disposed within and/or on the substrate 140. The DTI structure 165 may optically isolate the photodetector 82 from neighboring photodetectors 82.

An upper dielectric structure 167 is disposed over the back-side surface of the substrate 140. A grid structure 195 overlies the upper dielectric structure 165. The grid structure 195 may, for example, comprise a metal grid structure, a dielectric grid structure or both. The grid structure 195 is configured to direct the incident electromagnetic radiation to the underlying photodetector 82. In some embodiments, when the grid structure 195 comprises the metal grid structure (e.g., aluminum, copper, tungsten, or a combination of the foregoing), incident electromagnetic radiation may reflect off of sidewalls of the metal grid structure to the underlying photodetector 82 instead of traveling to an adjacent photodetector (see FIG. 1F). In such embodiments, the grid structure 195 may decrease cross talk between adjacent photodetectors 82. The grid structure 195 surrounds a color filter 180. The color filter 180 overlies the photodetector 82 and is configured to pass a first range of frequencies of the incident electromagnetic radiation while blocking a second range of frequencies of the incident electromagnetic radiation. The first range of frequencies is different than the second range of frequencies.

In some embodiments, as the incident electromagnetic radiation hits the back-side surface of the substrate 140, the incident electromagnetic radiation may travel through the photodetector 82 towards the front-side surface of the substrate. A portion of the incident electromagnetic radiation may travel through a thickness of the photodetector 82 towards the peripheral region. Subsequently, the incident electromagnetic radiation may bounce off of and/or reflect off of the vertical gate electrode 290 of the dummy vertical transistor structure 20d toward the front-side surface of the substrate 140. Further, the incident electromagnetic radiation may bounce off of and/or reflect off of a conductive layer or structure (e.g., the conductive wires and/or conductive vias) disposed within the interconnect structure 120. Additionally, after reflecting off of the conductive structure or layer within the interconnect structure 120, the incident electromagnetic radiation may hit and/or be absorbed by the photodetector 82. Therefore, the dummy vertical transistor structure 20d is configured to redirect the incident electromagnetic radiation away from the peripheral region of the image sensor IC 10C towards the interconnect structure 120 and/or towards the photodetector 82. This may prevent the incident electromagnetic radiation from traversing the peripheral region to another photodetector (e.g., the photodetector 82 of the pixel region 110b or of the pixel region 110c) disposed within the substrate 140 and adjacent to the photodetector 82, thereby decreasing cross talk between adjacent photodetectors and increasing a sensitivity of the photodetector 82.

The plurality of photodetectors 82 are within the substrate 140 at a point below the front-side surface of the substrate 140 and may comprise a second doping type (e.g., n-type doping) opposite the first doping type. The plurality of photodetectors 82 are disposed around the floating diffusion node 84, as shown in FIG. 1F. In some embodiments, a depletion region forms in and/or around each photodetector 82 (e.g., due to p-n junctions between the photodetectors 82 and p-type doping regions of the substrate 140 surrounding the photodetectors 82). The floating diffusion node 84 comprises the second doping type with a doping concentration greater than the substrate 140.

In some embodiments, as shown in FIG. 1E, the BDTI structure 165 overlaps the floating diffusion node 84 in the top view, for example, at the crossroad region 168 (see FIG. 1F). The BDTI structure 165 is formed following formation of the floating diffusion node 84, such that the floating diffusion node 84 underlies an opening in which the BDTI structure is formed. An etching process that forms the opening may suffer a loading effect at the crossroad regions 168, such that BDTI structure depth at the crossroad regions 168 is greater than that at the walls 166. This effect is worsened when the opening is formed using lower etching power. The worsened loading effect dramatically degrades isolation performance, as depth of the walls 166 is reduced to prevent the deeper depth of the crossroad region 168 resulting in contact with (e.g., damage to) the floating diffusion node 84.

FIG. 1G is a cross-sectional side view of an image sensor ICs 10D in accordance with various embodiments. The image sensor ICs 10D is similar in many respects to the image sensors 10A, 10B, 10C, and like reference numerals refer to like components.

Dimensions H1, H2, H3, W3, W4, W5 of the BDTI structure 165 are illustrated in FIG. 1G. As shown, the BDTI structure 165 may include first, second and third segments along the vertical direction (e.g., the Z-axis direction) having first, second and third heights H1, H2, H3, respectively. The first segment overlaps the floating diffusion region 84. The third segment is between the first segment and the floating diffusion region 84. The second segment is between the first segment and the third segment. The third segment may have width W3, the second segment may be tapered from width W3 to width W5, and the first segment may be tapered from width W5 to width W4. For example, the first segment has sidewalls that taper out with reduced distance from the floating diffusion region 84, and the second segment has sidewalls that taper in with reduced distance from the floating diffusion region 84. In some embodiments, the width W4 is less than the width W5 and greater than the width W3. The width W4 is associated with distance (e.g., one of diagonal distances D168B, D168C) between protrusions 140P of the substrate 140 at the upper surface of the substrate 140 in a crossroad region 168 (see FIG. 1F).

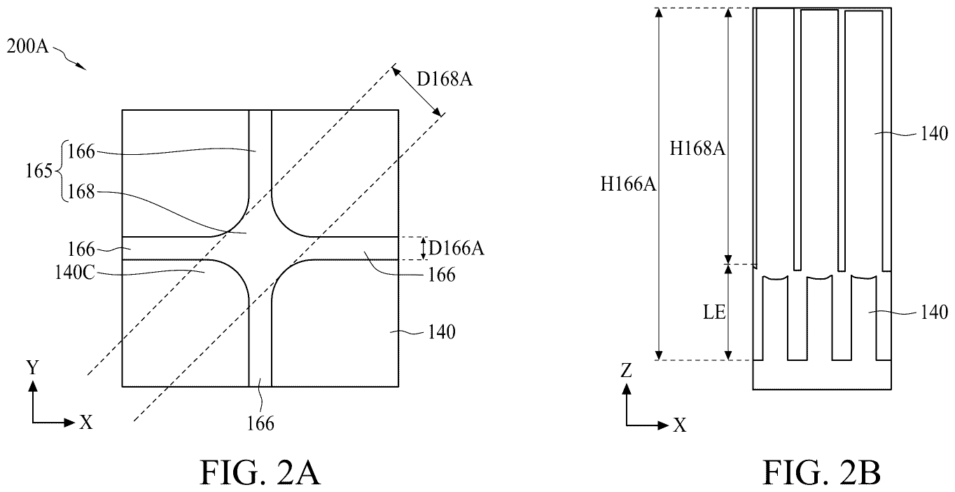

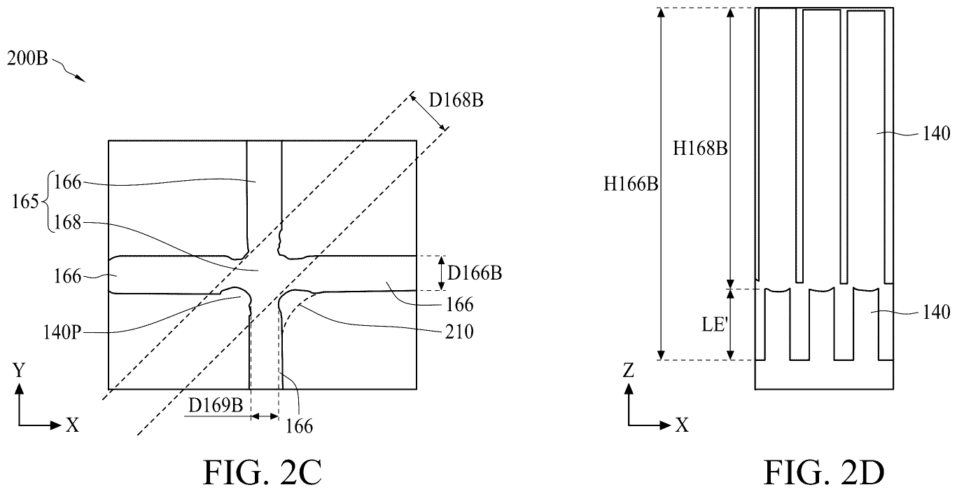

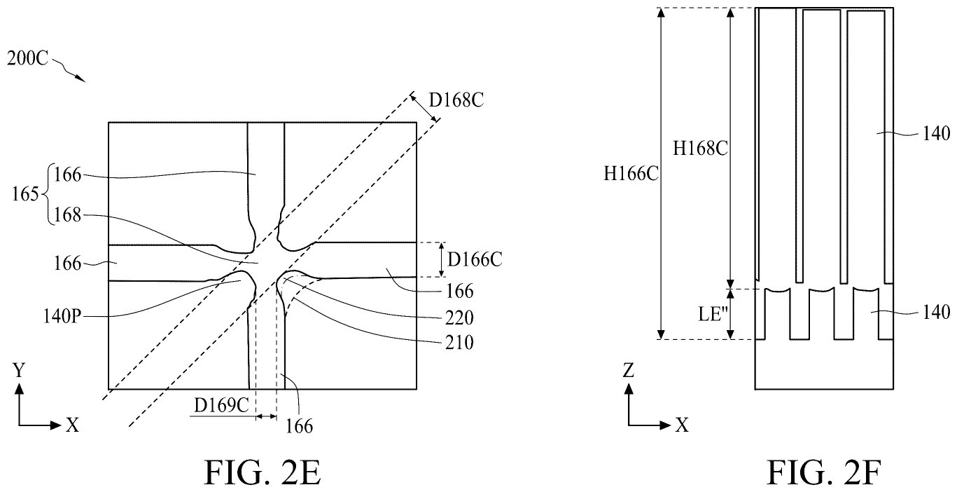

FIGS. 2A-2F illustrate the crossroad region 168 of the BDTI structure 165 in accordance with various embodiments. FIG. 2A is a top view of a region 200A including the crossroad region 168. FIG. 2B is a cross-sectional side view of crossroad regions 168 including the region 200A.

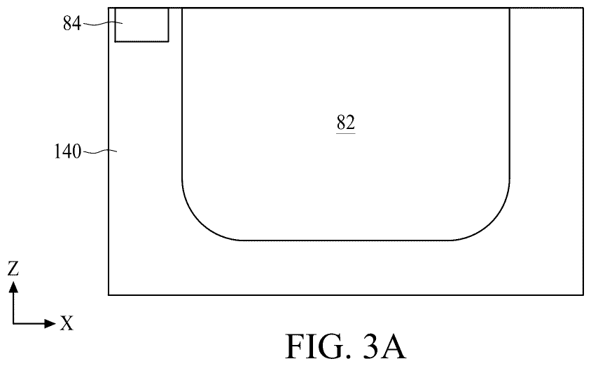

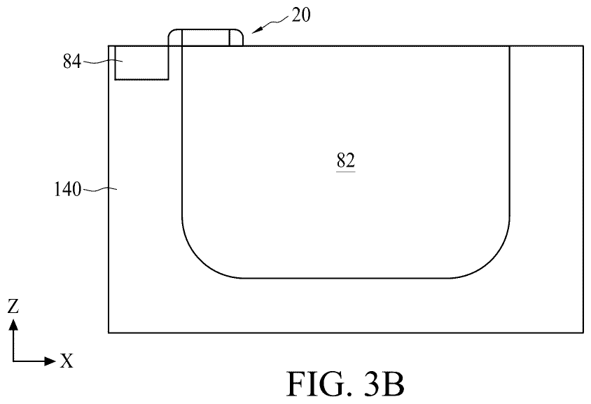

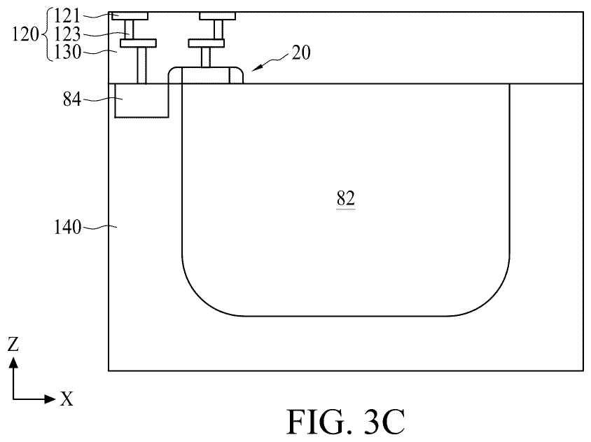

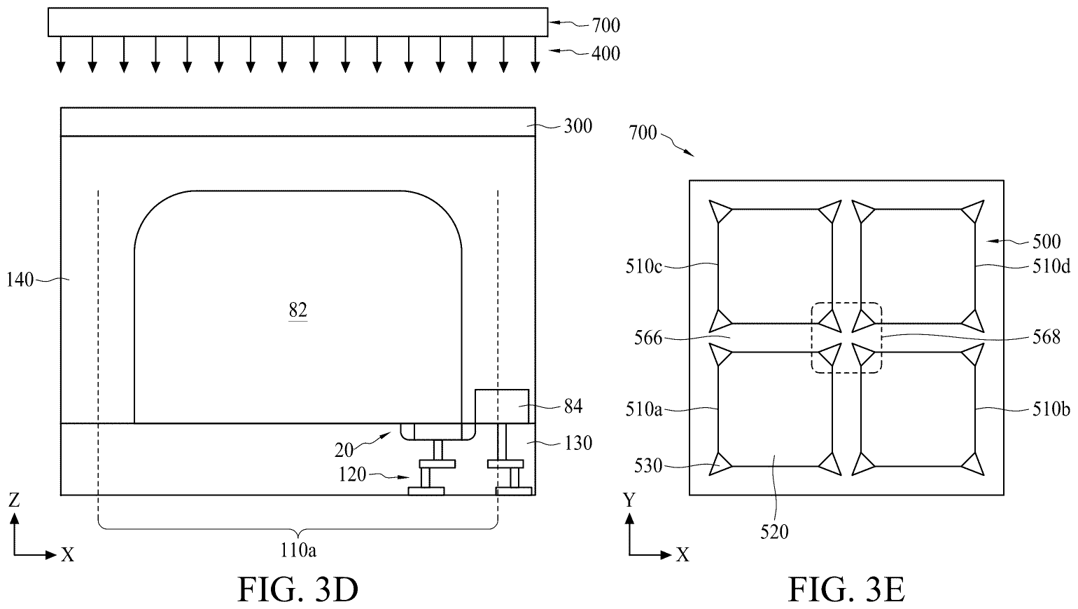

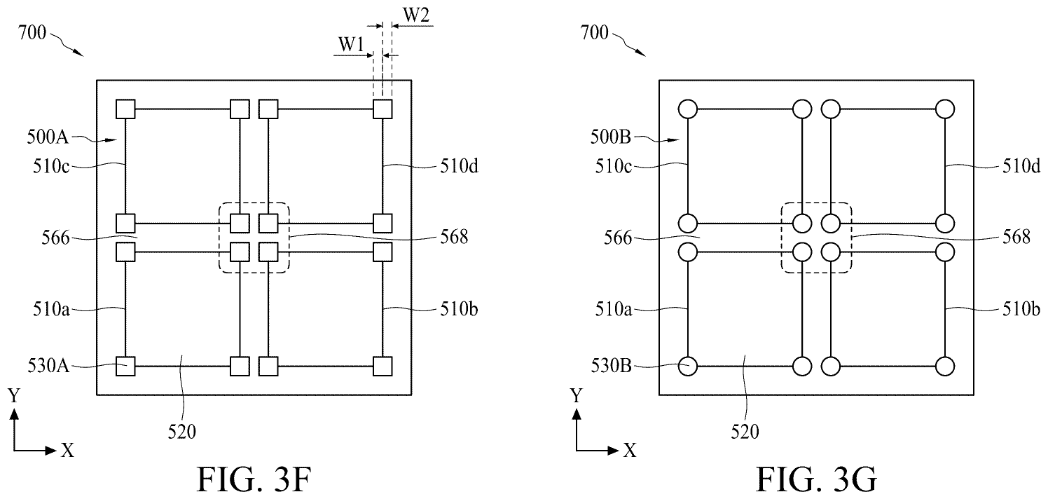

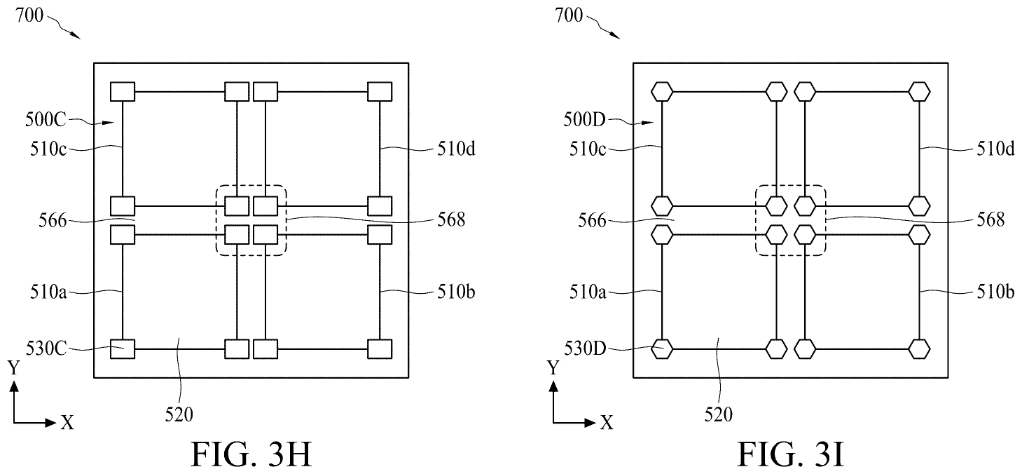

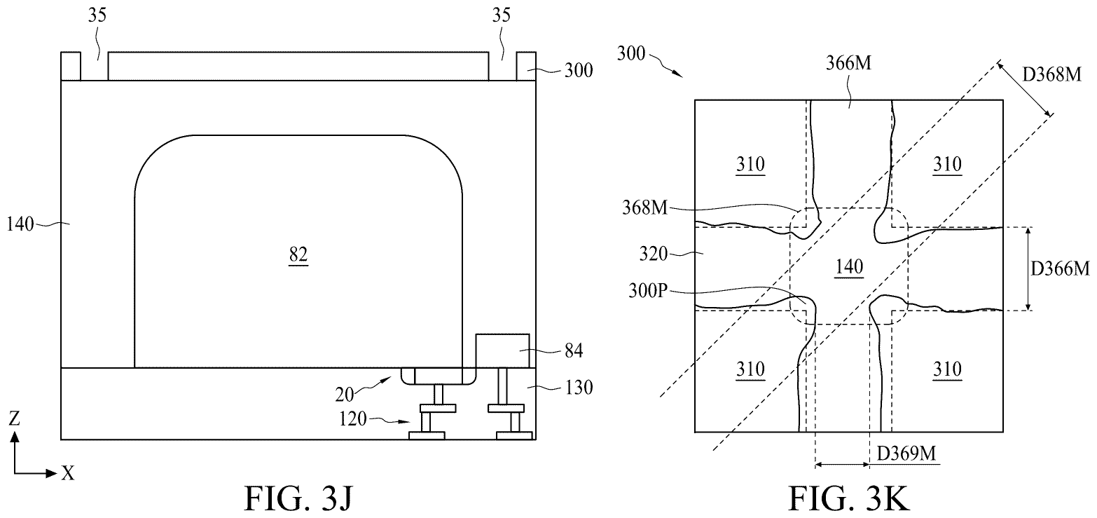

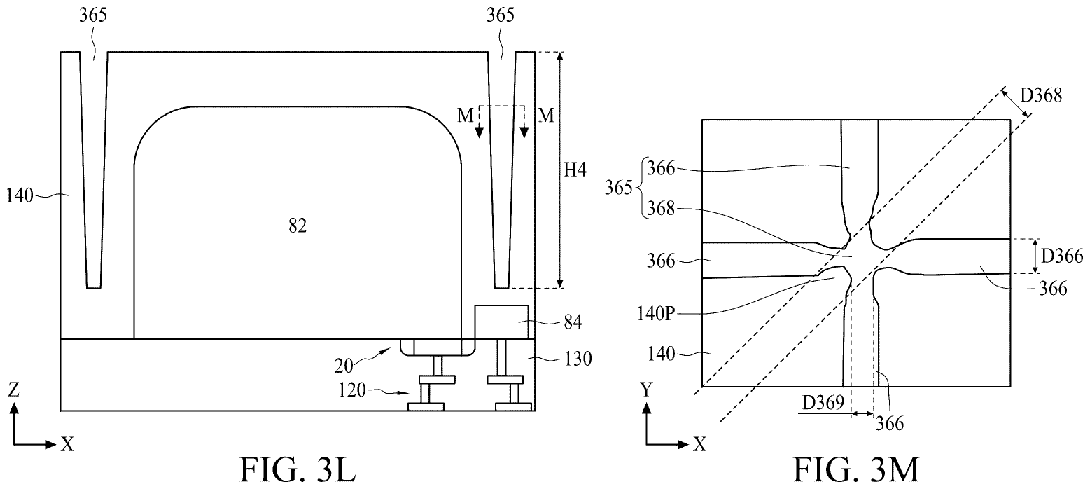

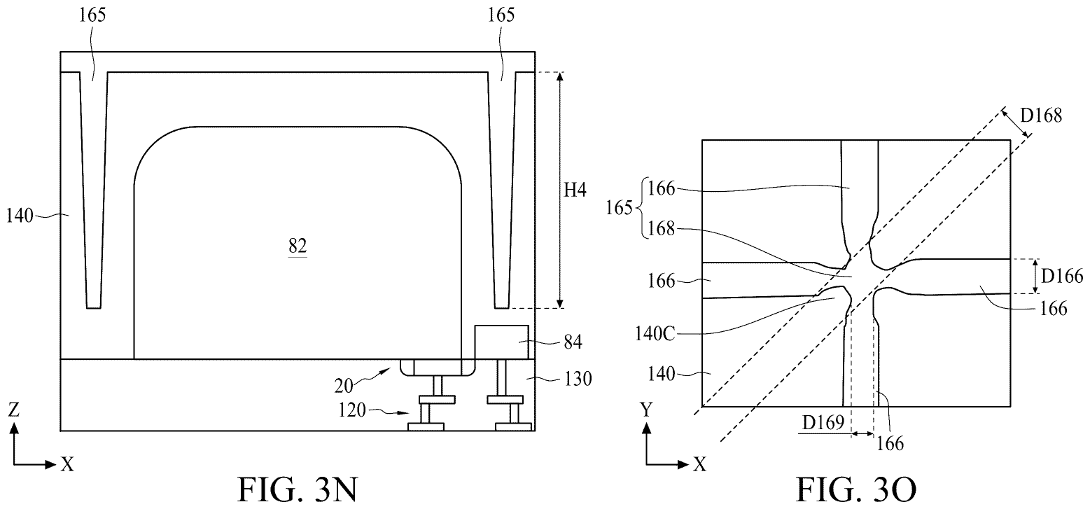

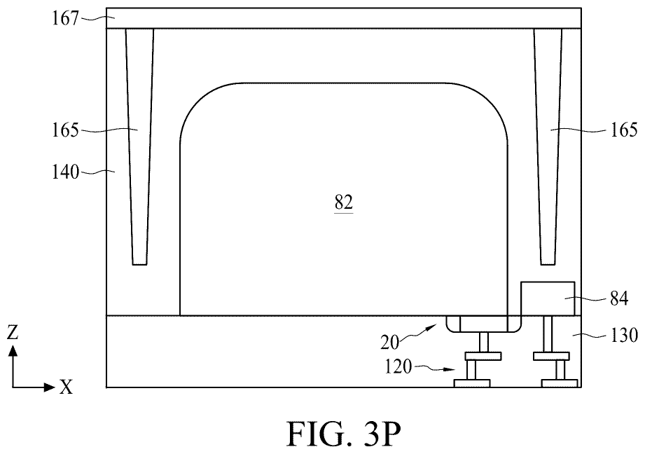

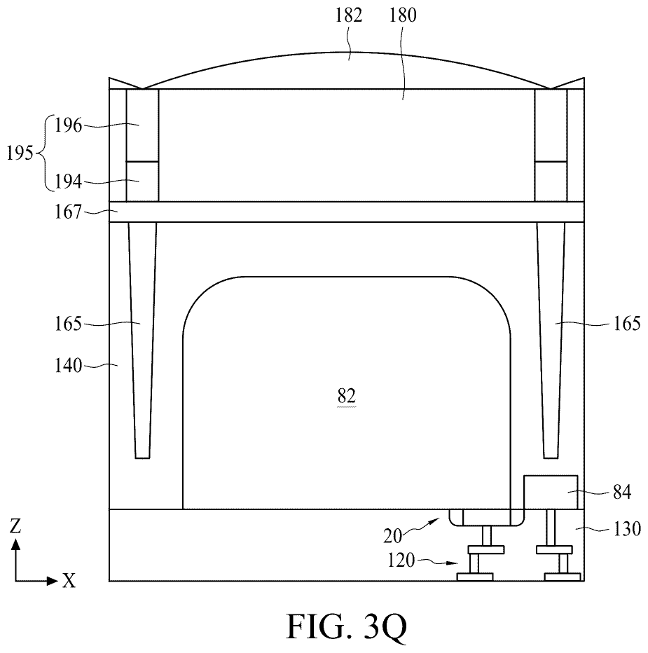

In FIG. 2A, the walls 166 have width D166A and the crossroad regions 168 have width D168A, as shown. The width D168A is the distance between diagonally opposed sidewalls of the BDTI structure 165 in the crossroad region 168. The width D168A is greater than the width D166A. In the region 200A shown in FIG. 2A, a ratio of the width D168A over the width D166A is greater than 1.414, such as 2 or more. The BDTI structure 165 shown in FIG. 2A is formed without use of OPC techniques described with reference to FIGS. 3E-3I. The substrate 140 has corner regions 140C abutting the crossroad region 168. In the region 200A, the corner regions 140C have a smoothly rounded profile, as shown, and is substantially free of protrusions 140P that are present in the regions 200B, 200C shown in FIGS. 2C and 2E.

As shown in FIG. 2B, the walls 166 have height H166A, and the crossroad regions 168 have height H168A. A height LE is the difference between the height H166A and the height H168A. As shown, the height H168A may not be uniform across the BDTI structure 165, and the height H166A may not be uniform across the BDTI structure 165. The loading effect is the height LE over the height H168A. In the region 200A, the loading effect is greater than about 30%.

In FIG. 2C, the BDTI structure 165 in a region 200B is formed using OPC techniques described with reference to FIGS. 3E-3I. In the region 200B, the walls 166 have width D166B, the crossroad regions 168 have diagonal width D168B, and the crossroad regions 168 have lateral width D169B, as shown. The diagonal width D168B is the distance between diagonally opposed sidewalls of the BDTI structure 165 in the crossroad region 168. The lateral width D169B is width (e.g., in the X-axis direction) between protrusions 140P in the crossroad region 168. FIG. 2C includes dashed line 210 illustrating profile of the corner region 140C for illustrative purposes. The diagonal width D168B is greater than the width D166B and the lateral width D169B. The diagonal width D168B is reduced relative to the width D168A of the region 200A in FIG. 2A due to presence of the protrusions 140P. In the region 200B, a ratio of the diagonal width D168B over the width D166B is less than 1.414. A ratio of the lateral width D169B over the width D166B is less than 1. The BDTI structure 165 shown in FIG. 2C is formed using one or more of the OPC techniques described with reference to FIGS. 3E-3I. The protrusions 140P of the substrate 140 abut the crossroad region 168. In the region 200B, the protrusions 140P have a sharper curved profile than the corner regions 140C, as shown. For example, radius of curvature of the protrusions 140P is less than radius of curvature of the corner regions 140C.

In FIG. 2D, the walls 166 have height H166B, and the crossroad regions 168 have height H168B. A height LE′ in FIG. 2D is the difference between the height H166B and the height H168B. As shown, the height H168B may not be uniform across the BDTI structure 165, and the height H166B may not be uniform across the BDTI structure 165. The loading effect is the height LE′ over the height H168B. The height LE′ is less than the height LE due to the protrusions 140P, which increase uniformity of etching between the crossroad regions 168 and the walls 166. In the region 200B, the loading effect is less than 30%, such as less than about 20%.

In FIG. 2E, the BDTI structure 165 in a region 200C is formed using OPC techniques described with reference to FIGS. 3E-3I. In the region 200C, the walls 166 have width D166C, the crossroad regions 168 have diagonal width D168C, and the crossroad regions 168 have lateral width D169C, as shown. The diagonal width D168C is the distance between diagonally opposed sidewalls of the BDTI structure 165 in the crossroad region 168. The lateral width D169C is width (e.g., in the X-axis direction) between protrusions 140P in the crossroad region 168. FIG. 2E includes dashed line 210 illustrating profile of the corner region 140C for illustrative purposes, and includes dashed line 220 illustrating profile of the protrusions 140P of the region 200B for illustrative purposes. The diagonal width D168C is greater than the width D166C and the lateral width D169C. The diagonal width D168C is reduced relative to the widths D168A, D168B of the regions 200A, 200B in FIGS. 2A, 2C due to presence of the protrusions 140P. In the region 200C, a ratio of the diagonal width D168C over the width D166C is less than 1.414, such as less than about 1.2. A ratio of the lateral width D169C over the width D166C is less than 1, such as less than about 0.8. The BDTI structure 165 shown in FIG. 2C is formed using one or more of the OPC techniques described with reference to FIGS. 3E-3I. The protrusions 140P of the substrate 140 abut the crossroad region 168. In the region 200C, the protrusions 140P have a sharper curved profile than the corner regions 140C and the protrusions 140P of the region 200B. For example, radius of curvature of the protrusions 140P of the region 200C is less than radius of curvature of the corner regions 140C and less than radius of curvature of the protrusions 140P of the region 200B.

In FIG. 2F, the walls 166 have height H166C, and the crossroad regions 168 have height H168C. A height LE″ in FIG. 2F is the difference between the height H166C and the height H168C. As shown, the height H168C may not be uniform across the BDTI structure 165, and the height H166C may not be uniform across the BDTI structure 165. The loading effect is the height LE″ over the height H168C. The height LE″ is less than the height LE and the height LE′ due to the protrusions 140P, which increases uniformity of etching between the crossroad regions 168 and the walls 166. In the region 200C, the loading effect is less than 30%, such as less than about 20%, such as less than about 18%.

In the embodiments illustrated in FIGS. 2C and 2E, a “diagonal ratio” equal to the diagonal width D168B over the width D166B (or equal to the diagonal width D168C over the width D166C) may be in a range of about 0.5 to 1.414. When the diagonal ratio is less than about 0.5, risk of merger of the protrusions 140P in the crossroad region 168 is insufficiently low. When the diagonal ratio is greater than 1.414, the loading effect of the BDTI structure 165 is insufficiently low. A “lateral ratio” equal to the lateral width D169B over the width D166B (or equal to the lateral width D169C over the width D166C) may be in a range of about 0.3 to 1. When the lateral ratio is less than about 0.3, risk of merger of the protrusions 140P in the crossroad region 168 is insufficiently low. When the lateral ratio is greater than 1, the loading effect of the BDTI structure 165 is insufficiently low.

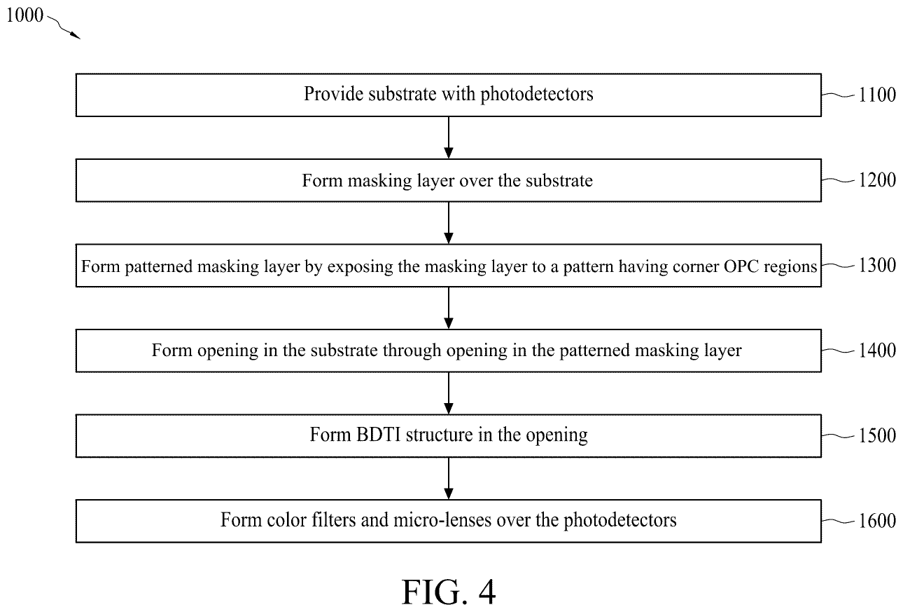

FIG. 4 illustrates a flowchart of a method 1000 for forming an IC device (e.g., the image sensor ICs 10A, 10B, 10C) or a portion thereof from a workpiece, according to one or more aspects of the present disclosure. Method 1000 is merely an example and is not intended to limit the present disclosure to what is explicitly illustrated in method 1000. Additional acts can be provided before, during and after the method 1000, and some acts described can be replaced, eliminated, or moved around for additional embodiments of the methods. Not all acts are described herein in detail for reasons of simplicity. Method 1000 is described below in conjunction with fragmentary perspective and/or cross-sectional views of a workpiece, shown in FIGS. 3A-3P, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 3A through 3P are views of intermediate stages in the manufacturing of an image sensor IC, in accordance with some embodiments.

In FIG. 3A, a substrate 140 is provided, corresponding to operation 1100 of FIG. 4. The substrate 140 may be a semiconductor substrate, such as a bulk semiconductor, or the like, which may be doped (e.g., with a p-type or an n-type dopant) or undoped. The semiconductor material of the substrate 140 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 3A, in some embodiments, a photodetector 82 is formed in the substrate 140. The photodetector 82 may comprise a first doped semiconductor region. A doping type of the first doped semiconductor region may be opposite a doping type of the substrate 140 such that together, the two form a p-n junction (e.g., a photodiode). A floating diffusion (FD) region 84 may also be formed in the substrate 140. In some embodiments, the first doped semiconductor region and the FD region 84 are formed in the substrate 140 by ion implantation or another suitable process. In some embodiments, the substrate 140 is provided with the photodetector 82, the floating diffusion region 84 or both already formed therein.

In FIG. 3B, following formation of the photodetector 82 and the FD region 84, a pixel transistor 20 may be formed on an upper surface of the substrate 140. The pixel transistor 20 may overlap the photodetector 82. In some embodiments, the pixel transistor 20 overlaps the photodetector 82 and the floating diffusion region 84.

In FIG. 3C, following formation of the pixel transistor 20, an interconnect structure 120 is formed over the upper surface of the substrate 140. The interconnect structure 120 includes an interconnect dielectric structure 130, a plurality of conductive wires 121, and a plurality of conductive vias 123. In some embodiments, the interconnect dielectric structure 120 may, for example, be or comprise an oxide (e.g., silicon dioxide), a nitride, a low-k dielectric, another suitable dielectric material, or the like. The interconnect dielectric structure 130 may be formed by CVD, PVD, ALD, or another suitable deposition process. The plurality of conductive wires 121 and/or the plurality of conductive vias 123 may be formed by a single damascene process or by a dual damascene process. The plurality of conductive wires and vias 121, 123 may, for example, each be or comprise aluminum, copper, tungsten, titanium nitride, a combination of the foregoing, or the like.

In FIGS. 3D-3N, following formation of the interconnect structure 120, BDTI structures 165 are formed, corresponding to operation 1200 through operation 1500 of FIG. 4.

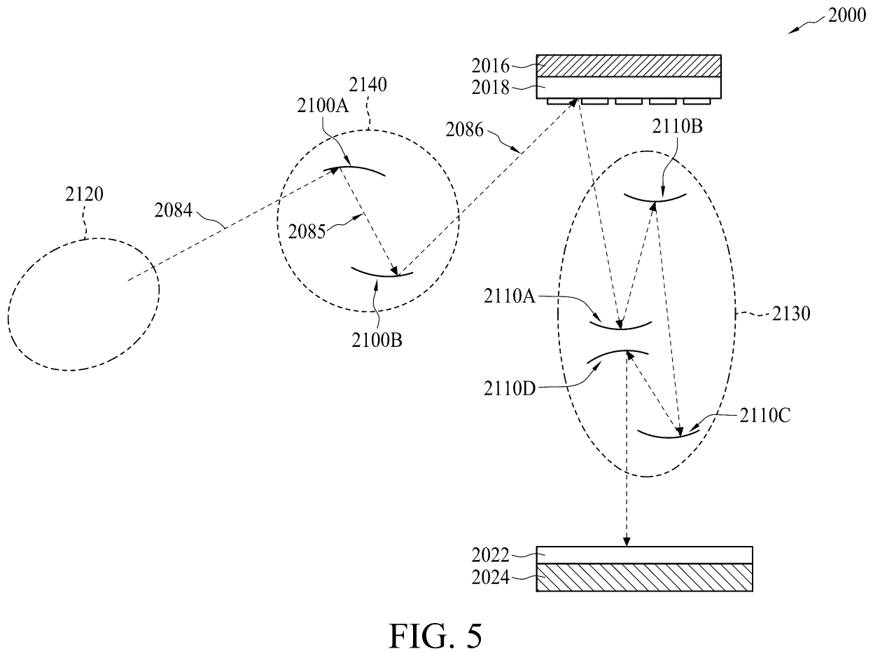

As illustrated in FIG. 3D, the structure of FIG. 3C is flipped, and a patterning process is performed into the back-side surface of the substrate 140. In some embodiments, the patterning process includes forming a masking layer 300 over the back-side surface of the substrate 140 (e.g., operation 1200), and exposing the masking layer 300 by a lithography process, such as an extreme ultraviolet (EUV) process, a deep ultraviolet (DUV) process, or the like, which may be performed by a lithography system, such as a lithography exposure system 2000 illustrated in FIG. 5. In the lithography process, the masking layer 300 is exposed to light 400 (e.g., EUV light, DUV light, or the like) having a pattern including OPC (e.g., operation 1300), such as a pattern 500 shown in FIG. 3E, a pattern 500A shown in FIG. 3F, a pattern 500B shown in FIG. 3G, a pattern 500C shown in FIG. 3H, a pattern 500D shown in FIG. 3I, or the like. In some embodiments, the pattern 500, 500A, 500B, 500C or 500D is part of a mask 700 of a lithography exposure system, such as a mask 2018 of the lithography exposure system 2000 (see FIG. 5). The mask 700 may be a photomask or reticle, which may be reflective. The light 400 may be reflected by the mask 700 toward the masking layer 300 according to the pattern 500, 500A, 500B, 500C or 500D. Following exposure to the light 400 having the pattern 500, 500A, 500B, 500C or 500D, exposed or unexposed regions of the masking layer 300 may be removed to form openings 35 (see FIG. 3J) that expose the substrate 140.

FIG. 3E illustrates the pattern 500 including OPC regions 530 for exposing the masking layer 300 by the light 400. The pattern 500 includes protection regions and exposure regions. The protection regions include four or more pixel protection regions 510a, 510b, 510c, 510d, which may be referred to collectively as the pixel protection regions 510a-510d. The pixel protection regions 510a-510d correspond to the pixel regions 110a-110d. The exposure regions include wall exposure regions 566 and crossroad exposure regions 568. The wall exposure regions 566 correspond to the wall 166 of FIG. 2C, for example, and the crossroad exposure regions 568 correspond to the crossroad region 168 of FIG. 2C, for example.

The pixel protection regions 510a-510d are associated with the pixel regions 110a-110d, respectively. For example, the pixel protection regions 510a-510d may be configured to reflect or absorb portions of the light 400 that are reflected onto first regions of the masking layer 300 substantially directly overlying the pixel regions 110a-110d, such that the first regions of the masking layer 300 remain after forming the openings 35 in FIG. 3J. The pixel protection regions 510a-510d include main regions 520 and OPC regions 530. The OPC regions 530 may be referred to as protrusion regions 530. In the example shown in FIG. 3E, the OPC regions 530 may be referred to as triangular protrusion regions 530. Although illustrated in FIG. 3E as separate components, the triangular protrusion regions 530 and the main regions 520 are generally present as a single, continuous region with no visible interface therebetween. The triangular protrusion regions 530 have a triangular shape, and extend toward the centers of the crossroad exposure regions 568. The triangular protrusion regions 530 are located at corner regions of the main regions 520.

The wall exposure regions 566 are between neighboring pairs of the pixel protection regions 510a-510d, such as between the pixel protection region 510a and the pixel protection region 510c, as labeled in FIG. 3E. The crossroad exposure regions 568 are between groups of four neighboring pixel protection regions, such as the pixel protection regions 510a-510d. The exposure regions, which include the wall exposure regions 566 and the crossroad exposure regions 568, may be configured to reflect or absorb portions of the light 400 that are reflected onto second regions of the masking layer 300 substantially directly overlying the walls 166 and the crossroad regions 168, respectively, such that the second regions of the masking layer 300 are removed by forming the openings 35 in FIG. 3J.

FIG. 3F is a view of the pattern 500A of the mask 700 in accordance with various embodiments. The pattern 500A is similar in many respects to the pattern 500 of FIG. 3E, and corresponding description of components thereof is provided with reference to FIG. 3E above. The pattern 500A includes square protrusion regions 530A having square shape. The square protrusion regions 530A extend toward centers of the crossroad exposure regions 568 and are located at corner regions of the main regions 520. As shown in FIG. 3F, the square protrusion regions 530A have a first dimension W1 and a second dimension W2. The first dimension W1 is a measure of overlap of the square protrusion region 530A with the main region 520. The second dimension W2 is a measure of extension of the square protrusion region 530A beyond the main region 530. A protrusion ratio is the ratio of the second dimension W2 over the first dimension W1. For the same area of square shape of the square protrusion region 530A, an increase in the protrusion ratio (W2/W1) results in a decrease in the loading effect. For example, as illustrated in FIGS. 2A, 2C and 2E, the protrusion ratio used to form the BDTI structure 165 in FIG. 2A is less than the protrusion ratio used to form the BDTI structure 165 in FIG. 2C, which is less than the protrusion ratio used to form the BDTI structure 165 in FIG. 2E. As a result, the loading effect of the BDTI structure 165 illustrated in FIG. 2A is greater than the loading effect of the BDTI structure 165 illustrated in FIG. 2C, which is greater than the loading effect of the BDTI structure 165 illustrated in FIG. 2E. In some embodiments, the protrusion ratio is in a range of about 0.1 to about 10.

FIG. 3G is a view of the pattern 500B of the mask 700 in accordance with various embodiments. The pattern 500B is similar in many respects to the patterns 500, 500A, and corresponding description of components thereof is provided with reference to FIG. 3E and FIG. 3F above. The pattern 500B includes circular protrusion regions 530B having circular shape.

FIG. 3H is a view of the pattern 500C of the mask 700 in accordance with various embodiments. The pattern 500C is similar in many respects to the patterns 500, 500A, 500B, and corresponding description of components thereof is provided with reference to FIGS. 3E, 3F and 3G above. The pattern 500C includes rectangular protrusion regions 530C having rectangular shape. In some embodiments, the rectangular shape has a length dimension that is longer than a width dimension thereof. In some embodiments, the rectangular protrusion regions 530C all have the same orientation, such as longer sides thereof extending along the X-axis direction, as shown in FIG. 3H. In some embodiments, some of the rectangular protrusion regions 530C may extend in a first direction (e.g., the X-axis direction) and others of the rectangular protrusion regions 530C may extend in a second direction (e.g., the Y-axis direction) that is transverse the first direction. In some embodiments, one or more of the rectangular protrusion regions 530C is oriented with an angular offset relative to direction of extension of the wall exposure regions 566 (e.g., an angular offset relative to the X-axis direction or the Y-axis direction). The angular offset may be greater than 0 degrees and less than 90 degrees.

FIG. 3I is a view of the pattern 500D of the mask 700 in accordance with various embodiments. The pattern 500D is similar in many respects to the patterns 500, 500A, 500B, 500C, and corresponding description of components thereof is provided with reference to FIGS. 3E, 3F, 3G and 3H above. The pattern 500D includes N-sided protrusion regions 530D having N-sided shape, in which “N” is an integer greater than or equal to five. In the example shown in FIG. 3I, “N” is equal to six, such that the N-sided protrusion regions 530D as hexagonal shape. In some embodiments, the N-sided shape is substantially regular, such that internal angles of the N-sided shape are all the same, and side lengths of the N-sided shape are all the same. In some embodiments, the hexagonal shape is irregular, such that one or more of the N angles or N sides thereof is different from others of the N angles or N sides, respectively. In some embodiments, the N-sided protrusion regions 530D all have the same orientation, as shown in FIG. 3I. In some embodiments, some of the N-sided protrusion regions 530D may be oriented in a first direction (e.g., the X-axis direction) and others of the N-sided protrusion regions 530D may be oriented in a second direction (e.g., the Y-axis direction) that is transverse the first direction. In some embodiments, one or more of the N-sided protrusion regions 530D is oriented with an angular offset relative to direction of extension of the wall exposure regions 566 (e.g., an angular offset relative to the X-axis direction or the Y-axis direction). The angular offset may be greater than 0 degrees and less than 90 degrees.

In FIGS. 3J and 3K, following exposure to the light 400 having the pattern 500, 500A, 500B, 500C or 500D as shown in FIGS. 3D-3I, exposed or unexposed regions of the masking layer 300 may be removed to form openings 35 that expose the substrate 140. The openings 35 in the masking layer 300 include wall exposure regions 366M and a mask crossroad region 368M. The wall exposure regions 366M may include horizontal wall exposure regions and vertical wall exposure regions. The wall exposure regions 366M may have width D366M. The masking layer 300 may include mask protrusion regions 300P. The mask protrusion regions 300P extend into the mask crossroad region 368M beyond mask pixel regions 310. The protrusion regions 300P may be separated by a diagonal distance D368M and by a lateral distance D369M, as shown in FIG. 3K. The mask crossroad region 368M may be associated with (e.g., substantially overlap in the top view) the crossroad region 168 of the BDTI structure 165. Protrusion of the mask protrusion regions 300P is illustrated conceptually in FIG. 3K as portions of the masking layer 300 that extend beyond dotted lines 320 that correspond to, for example, simulated or intended location of the mask pixel regions 310.

In FIGS. 3L and 3M, following formation of the openings 35, openings 365 are formed in regions of the substrate 140 exposed by the openings 35 of the masking layer 300, corresponding to operation 1400 of FIG. 4. The openings 365 may be formed by exposing unmasked regions of the substrate 140 to one or more etchants. As shown in FIG. 3L, the openings 365 extend from the upper surface of the substrate 140 (relative to the page of FIG. 3L) to a level above the upper surface of the floating diffusion region 84, and have height H1. As shown in FIG. 3M, the openings 365 include wall openings 366 and crossroad openings 368. The wall openings 366 have width D366. A lateral distance D369 is present between neighboring protrusion regions 140P of the substrate 140, as shown in FIG. 3M. A diagonal distance D368 is present between protrusion regions 140P that are diagonally opposite each other, as shown. As shown in FIG. 3L, sidewalls of the openings 35 may be tapered, narrowing with increased proximity to the floating diffusion region 84 (e.g., in the negative Z-axis direction), for example. In some embodiments, aspect ratio of the openings 35 may be in a range of about 10 to about 100. In some embodiments, aspect ratio of the openings 35 is greater than 100. The aspect ratio may be the ratio of the height H4 over the diagonal distance D368. The aspect ratio may be the ratio of the height H4 over the width D366. In some embodiments, the height H4 is within a range of about 2 to about 4 micrometers, or may be greater than about 4 micrometers. Following formation of the openings 365, a removal process may be performed to remove the masking layer 300. In some embodiments, the openings 365 are a single opening in the form of, for example, a grid.

In FIGS. 3N and 3O, the BDTI structures 165 are formed in the substrate 140, thereby filling (e.g., completely filling or partially filling) the openings 365 of FIGS. 3L and 3M, corresponding to operation 1500 of FIG. 4. In some embodiments, the BDTI structures 165 may, for example, be or comprise an oxide, such as silicon dioxide, another suitable oxide, or the like. In some embodiments, the BDTI structure 165 is formed by a chemical vapor deposition (CVD) process, an atomic layer deposition (ALD) process, or other suitable process. After depositing the BDTI structure 165 by the ALD process, an optional planarization process (e.g., chemical mechanical planarization (CMP)) process may be performed to remove excess material of the BDTI structures 165 overlying the substrate 140. In such embodiments, the BDTI structures 165 may have a substantially flat upper surface. In some embodiments, the CMP process removes a portion of the excess material while leaving a layer of the material over the substrate 140, the layer having a substantially flat upper surface. In some embodiments, the BDTI structures 165 extend from the upper surface of the substrate 140 to a point below the upper surface by the height H4. In some embodiments, the height H4 is within a range of about 2 micrometers to about 4 micrometers, or may be greater than about 4 micrometers. The substrate 140 may have thickness (e.g., in the Z-axis direction) in a range of about 3 micrometers to about 5 micrometers. In some embodiments, aspect ratio of the BDTI structures 165 may be in a range of about 10 to about 100. In some embodiments, aspect ratio of the BDTI structures 165 is greater than 100. The aspect ratio may be the ratio of the height H4 over the diagonal distance D168. The aspect ratio may be the ratio of the height H4 over the width D166.

In FIG. 3P, following formation of the BDTI structures 165, a buffer layer 167, which may be a dielectric layer, is formed over the upper surface of the BDTI structure 165. The buffer layer 167 may be formed by, for example, CVD, PVD, ALD, thermal oxidation, or another suitable growth or deposition process. The buffer layer 167 may be or comprise an oxide, such as silicon dioxide, or another suitable dielectric material. In some embodiments, after depositing the buffer layer 167, a planarization process (e.g., a CMP) is performed on the buffer layer 167, such that the buffer layer 167 has a substantially flat upper surface.

In FIG. 3Q, color filters 180 and micro-lenses are formed over the photodetectors 82, corresponding to operation 1600 of FIG. 4. Following formation of the buffer layer 167, a grid structure 195 and the color filters 180 are formed over the buffer layer 167. In some embodiments, the grid structure 195 may include a first grid layer 194 that extends across an upper surface of the buffer layer 167 and a second grid layer 196 that overlies the first grid layer 194. The first grid layer 194, the second grid layer 196 or both may be or comprise a dielectric material, a conductive material or both. In some embodiments, the first and second grid layers 194, 196 may be formed by CVD, PVD, ALD, sputtering, electroless plating, or another suitable growth or deposition process.

Following deposition of the first and second grid layers 194, 196, a patterning process may be performed on the first and second grid layers 194, 196 to form color filter openings. Subsequently, the color filters 180 may be formed in the color filter openings, such that the grid structure 195 continuously surrounds the color filters 180. In some embodiments, the color filters 180 may be formed by forming various color filter layers and patterning the color filter layers. The color filter layers are formed of material that allows for the transmission of incident radiation (e.g., light) having a selected wavelength range, while blocking light of wavelengths outside of the selected wavelength range. In some embodiments, the color filter layers may be planarized (e.g., via CMP) subsequent to formation.

Also illustrated in FIG. 3Q, a plurality of micro-lenses 182 are formed over the substrate 140. In some embodiments, the micro-lenses 182 may be formed by depositing a micro-lens material over the substrate 140 (e.g., by a spin-on method or a deposition process). A micro-lens template (not shown) having a curved upper surface is patterned above the micro-lens material. The micro-lenses 182 are then formed by selectively etching the micro-lens material according to the micro-lens template.

FIG. 5 is a schematic and diagrammatic view of a lithography exposure system 2000 which may be used to perform operation 1300 of FIG. 4, in accordance with some embodiments. In some embodiments, the lithography exposure system 2000 is an extreme ultraviolet (EUV) lithography system designed to expose a resist layer, such as the masking layer 300 shown in FIG. 3D, by EUV radiation, and may also be referred to as the EUV system 2000. The lithography exposure system 2000 may be an EUV scanner. The lithography exposure system 2000 includes a light source 2120, an illuminator 2140, a mask stage 2016, a projection optics module (or projection optics box (POB)) 2130 and a substrate stage 2024, in accordance with some embodiments. The elements of the lithography exposure system 2000 can be added to or omitted, and the disclosure should not be limited by the embodiment.

The light source 2120 is configured to generate light radiation having a wavelength ranging between about 1 nm and about 100 nm in certain embodiments. In one particular example, the light source 2120 generates an EUV radiation with a wavelength centered at about 13.5 nm. Accordingly, the light source 2120 is also referred to as an EUV radiation source. However, it should be appreciated that the light source 2120 should not be limited to emitting EUV radiation. The light source 2120 can be utilized to perform any high-intensity photon emission from excited target fuel.

In various embodiments, the illuminator 2140 includes various refractive optic components, such as a single lens or a lens system having multiple reflectors 2100A, 2100B, for example lenses (zone plates) or alternatively reflective optics (for EUV lithography exposure system), such as a single mirror or a mirror system having multiple mirrors in order to direct light from the light source 2120 onto the mask stage 2016, particularly to a mask 2018 secured on the mask stage 2016. The mask 2018 may include any of the patterns 500, 500A, 500B, 500C, 500D described with reference to FIGS. 3E-3I. In the present embodiment where the light source 2120 generates light 2084 in the EUV wavelength range, reflective optics are employed, to generate light 2085, 2086. In some embodiments, the illuminator 2140 includes at least three lenses. The reflector 2100A may be a field facet mirror (FFM), in some embodiments. The reflector 2100B may be a pupil facet mirror (PFM) in some embodiments. The reflector 2100A is configured to block radiation reflected from contaminated regions of the light source 2120.

The mask stage 2016 is configured to secure the mask 2018. In some embodiments, the mask stage 2016 includes an electrostatic chuck (e-chuck) to secure the mask 2018. This is because gas molecules absorb EUV radiation and the lithography exposure system for the EUV lithography patterning is maintained in a vacuum environment to avoid EUV intensity loss. In the present disclosure, the terms mask, photomask, and reticle are used interchangeably. In the present embodiment, the mask 2018 is a reflective mask. One exemplary structure of the mask 2018 includes a substrate with a suitable material, such as a low thermal expansion material (LTEM) or fused quartz. In various examples, the LTEM includes TiO₂ doped SiO₂, or other suitable materials with low thermal expansion. The mask 2018 includes a reflective multilayer deposited on the substrate. In some embodiments, the reflective multilayer includes one or more of the patterns 500, 500A, 500B, 500C, 500D described with reference to FIGS. 3E-3I.

The projection optics module (or projection optics box (POB)) 2130 is configured for imaging the pattern of the mask 2018 on to a semiconductor wafer 2022 secured on the substrate stage 2024 of the lithography exposure system 2000. In some embodiments, the POB 2130 has refractive optics (such as for a UV lithography exposure system) or alternatively reflective optics (such as for an EUV lithography exposure system) in various embodiments. The light directed from the mask 2018 (e.g., the light 400 shown in FIG. 3D), carrying the image of the pattern defined on the mask, is collected by the POB 2130. The illuminator 2140 and the POB 2130 are collectively referred to as an optical module of the lithography exposure system 2000. In some embodiments, the POB 2130 includes at least six reflective optics. In some embodiments, the POB 2130 includes a first mirror 2110A, a second mirror 2110B, a third mirror 2110C and a fourth mirror 2110D.

In the present embodiment, the semiconductor wafer 2022 may be made of silicon or other semiconductor materials. Alternatively or additionally, the semiconductor wafer 2022 may include other elementary semiconductor materials such as germanium (Ge). In some embodiments, the semiconductor wafer 2022 is made of a compound semiconductor such as silicon carbide (SiC), indium arsenide (InAs), or indium phosphide (InP). In some embodiments, the semiconductor wafer 2022 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 2022 may be a silicon-on-insulator (SOI) or a germanium-on-insulator (GOI) substrate.

In addition, the semiconductor wafer 2022 may have various device elements. Examples of device elements that are formed in the semiconductor wafer 2022 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, resistors, capacitors, other applicable elements, combinations thereof, or the like. Various processes are performed to form the device elements, such as deposition, etching, implantation, photolithography, annealing, and/or other suitable processes. In some embodiments, the semiconductor wafer 2022 is coated with a resist layer (e.g., the masking layer 300) sensitive to the EUV radiation in the present embodiment. Various components including those described above are integrated together and are operable to perform lithography processes.

The lithography exposure system 2000 may further include other modules or be integrated with (or be coupled with) other modules, such as a cleaning module designed to provide hydrogen gas to the light source 2120. The hydrogen gas helps reduce contamination in the light source 2120.

Embodiments may provide advantages. An improved optical proximity correction (OPC) process for exposing the masking layer 300 reduces diagonal width D368M of the opening 35 in the masking layer 300 used when etching the opening 365 in which the BDTI structure 165 is formed. By reducing dimensions of the crossroad region 368 of the masking layer 300, loading effect at the crossroad regions 168 of the BDTI structure 165 is reduced. Improvements to the BDTI structure 165, including increased depth uniformity, enable smaller pixel sizes not only for partial BDTI structures but also for full BDTI structures, which enables image sensor ICs having increased pixel density.

In accordance with at least one embodiment, a method includes: forming a masking layer on a backside of a substrate, the substrate including pixel regions having photodetectors, transistors being positioned on or in a frontside of the substrate; forming a mask opening in the masking layer by exposing the masking layer to patterned light, the mask opening including: mask pixel regions that mask the pixel regions; and mask protrusion regions that extend from the mask pixel regions toward a mask crossroad region; forming a substrate opening in the substrate by etching the substrate through the mask opening; and forming an isolation structure in the substrate opening.

In accordance with at least one embodiment, a device includes a substrate, a photodetector in the substrate, a transistor on or in a first side of the substrate, and an isolation structure in the substrate, the isolation structure laterally surrounding the photodetector. The isolation structure includes: a first wall extending in a first direction, the first wall having a first width; a second wall extending in a second direction transverse the first direction; and a crossroad region positioned at a region of overlap of the first wall with the second wall, the crossroad region having a second width that is narrower than the first width.

In accordance with at least one embodiment, a method includes: forming a photodetector in a substrate; forming a transistor on a first side of the substrate; and forming a patterned mask on a second side of the substrate, the second side facing away from the first side. The patterned mask includes wall exposure regions. The wall exposure regions include: first wall exposure regions extending in a first direction, the first wall exposure regions having a first width; and second wall exposure regions extending in a second direction, the second direction being transverse the first direction. The patterned mask further includes crossroad regions at regions of overlap of the first wall exposure regions with the second wall exposure regions, the crossroad regions having a second width narrower than the first width. The method further includes: forming an opening in the substrate by etching through the patterned mask; and forming an isolation structure in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A device comprising:
a substrate;
a photodetector in the substrate;
a transistor on or in a first side of the substrate; and
an isolation structure in the substrate, the isolation structure laterally surrounding the photodetector, the isolation structure including:
a first wall extending in a first direction, the first wall having a first width;
a second wall extending in a second direction transverse the first direction; and
a crossroad region positioned at a region of overlap of the first wall with the second wall, the crossroad region having a second width that is narrower than the first width.

2. The device of claim 1, wherein the substrate includes:
a first pixel region including the photodetector;
a second pixel region positioned across the first wall from the first pixel region along the second direction;
a first protrusion extending from the first pixel region toward the center of the crossroad region; and
a second protrusion extending from the second pixel region toward the center of the crossroad region.

3. The device of claim 2, wherein the first protrusion is separated from the second protrusion by the second width.

4. The device of claim 1, wherein the substrate includes:
a first pixel region including the photodetector;
a second pixel region positioned diagonally across the first wall and the second wall from the first pixel region;
a first protrusion extending from the first pixel region toward the center of the crossroad region; and
a second protrusion extending from the second pixel region toward the center of the crossroad region.

5. The device of claim 4, wherein the first protrusion is separated from the second protrusion by a third width, a ratio of the third width over the first width being less than 1.414.

6. The device of claim 1, further comprising:
a floating diffusion region in the substrate, the floating diffusion region overlapping the isolation structure.

7. The device of claim 1, wherein the crossroad region has a cross-sectional profile including:
a first segment overlapping the floating diffusion region, the first segment abutting at least two protrusions of the substrate;
a third segment between the first segment and the floating diffusion region; and
a second segment between the first segment and the third segment;
wherein the first segment has sidewalls that taper out with reduced distance from the floating diffusion region;
wherein the second segment has sidewalls that taper in with reduced distance from the floating diffusion region.

8. The device of claim 7, wherein height of the second segment is greater than height of the first segment.

9. A device, comprising:
a dielectric structure having a first side and a second side opposite to the first side;
a plurality of transistors in the substrate at the first side of the dielectric structure;
a plurality of conductive interconnect structures, each respective conductive interconnect structure of the plurality of conductive interconnect structures extend into the second side of the dielectric structure to a respective transistor of the plurality of transistors;
a substrate on the first side of the dielectric structure, the substrate including ga third side on the first side of the dielectric structure and a fourth side opposite to the third side;
a plurality of photodetectors within the substrate;
a shallow trench isolation (STI) structure is within the substrate, extends outward from the first side of the dielectric structure, and extends into the third side of the substrate;
a deep trench isolation (DTI) structure is within the substrate, extends into the fourth side of the substrate, and is aligned with the STI structure; and
a plurality of pixel regions in the substrate defined and delimited by the STI structure and the DTI structure, each respective pixel region of the plurality of pixels regions includes a respective photodetector of the plurality of photodetectors.

10. The device of claim 9, wherein the DTI structure terminates within the substrate before reaching the STI structure.

11. The device of claim 9, wherein the fourth side of the substrate has a plurality of topographical features arranged along the plurality of pixel regions.

12. The device of claim 11, further comprising one or more dielectric layers on the fourth side of the substrate, and the one or more dielectric layers cover the plurality of topographical features arranged along the plurality of pixel regions.

13. The device of claim 12, wherein the DTI structure includes a respective end surface exposed from the fourth side of the substrate, and the respective end surface is covered by the one or more dielectric layers.

14. The device of claim 9, wherein:
the STI structure includes a first segment and a second segment that intersect each other at a crossroad region, and the first segment and the second segment of the STI structure define a first plus-shaped portion of the STI structure; and
the DTI structure includes a third segment and a fourth segment that intersect each other at the crossroad region, and the third segment and the fourth segment define a second plus-shaped portion of the DTI structure.

15. The device of claim 14, wherein the first plus-shaped portion of the STI structure aligned with and overlapped by the second plus-shaped portion of the DTI structure.

16. The device of claim 15, wherein the first plus-shaped portion of the STI structure and the second-plus shaped portion of the DTI structure define and delimit the plurality of pixel regions.

17. A device, comprising:
a dielectric structure having a first side and a second side opposite to the first side;
a plurality of transistors in the substrate at the first side of the dielectric structure;
a plurality of conductive interconnect structures, each respective conductive interconnect structure of the plurality of conductive interconnect structures extend into the second side of the dielectric structure to a respective transistor of the plurality of transistors;
a substrate on the first side of the dielectric structure, the substrate including ga third side on the first side of the dielectric structure and a fourth side opposite to the third side;
a plurality of photodetectors within the substrate;
a deep trench isolation (DTI) structure is within the substrate and extends into the fourth side of the substrate; and
a plurality of pixel regions in the substrate defined and delimited by the STI structure and the DTI structure, each respective pixel region of the plurality of pixels regions includes a respective photodetector of the plurality of photodetectors.

18. The device of claim 17, wherein the DTI structure includes a third segment and a fourth segment that intersect each other at the crossroad region, and the third segment and the fourth segment define a plus-shaped portion of the DTI structure, and the plus shaped portion of the DTI structure define and delimit the plurality of pixel regions.

19. The device of claim 17, wherein each respective photodetector of the plurality of photo detectors is aligned with a respective center of each respective pixel region of the plurality of pixel regions.

20. The device of claim 17, wherein each respective photodetector of the plurality of photo detectors is offset from a respective center of each respective pixel region of the plurality of pixel regions.
